(19) United States
(12) Patent Application Publication
(10) Pub. No.: US 2026/0282574 A1
(43) Pub. Date: Sep. 17, 2026

(54) WAFER LEVEL OPTICAL SENSOR PACKAGING

(71) Applicant: STMicroelectronics International N.V., Geneva (CH)

(72) Inventor: Jing-En LUAN, Singapore (SG)

(73) Assignee: STMicroelectronics International N.V., Geneva (CH)

(21) Appl. No.: 19/075,942

(22) Filed: Mar. 11, 2025

(51) Int. Cl. H10F 39/00

(52) U.S. Cl. CPC H10F 39/804; H10F 39/024; H10F 39/026; H10F 39/8057

(57) ABSTRACT

A package includes a silicon integrated circuit substrate die including a die area for an optical function such as light sensing or light emitting. A micro-dam structure surrounds the die area. The micro-dam structure delimits a reservoir that is filled with a transparent material. An opaque material laterally encapsulates the micro-dam structure filled by the transparent material.

### TECHNICAL FIELD

The present disclosure generally relates to sensor packaging and, in particular, to wafer level optical sensor packaging.

### BACKGROUND

Electronic sensor technology is currently being incorporated into many consumer products, including automobiles, appliances, and mobile devices such as smart phones. Electronic micro-sensor devices can be used to detect environmental conditions such as temperature, humidity, rainfall, sounds, and the like. Such devices can also be used to detect modes of operation of consumer appliances in which they are installed, such as the orientation of a smart phone, use of voice commands, ambient light, and the like. Micro-sensors offer many advantages due to their size, reliability, and low cost. As electronic micro-sensors become smaller and less expensive, they are in higher demand.

One example of an electronic micro-sensor is a proximity sensor that detects the presence of nearby objects without a need for physical contact. Some proximity sensors emit a light beam that is reflected from a target object. The reflected light beam is then captured by the proximity sensor and compared with the emitted beam or with an ambient light level to detect changes that can yield information about the target object. One specific implementation of such a sensor is known to those skilled in the art as a Time of Flight (ToF) sensor that measures a time difference between emission of the light beam and return of the light beam reflected by the target to calculate a distance to the target.

Reference is now made to FIG. 1 which shows a cross-sectional view of a conventional ToF optical sensor package 100. The package 100 includes a sensor integrated circuit die 112 mounted to a substrate 104. The substrate 104 may, for example, comprise a printed circuit board including front connection pads 106, rear connection pads 108 and an electrical connection network 110 (with lines and vias) for electrically connecting the front and rear connection pads. The sensor integrated circuit die 112 is mounted to the front surface of the substrate 104 and front bonding pads of the die are electrically connected to the front connection pads 106 by bonding wires. The sensor integrated circuit die 112 includes a photosensitive region 116. An emitter integrated circuit die 114 is mounted to a front bonding pad at the front surface of the sensor integrated circuit die 112 and electrically connected to one or more other front bonding pads of the die by one or more bonding wires. The emitter integrated circuit die 114 includes a photoemission region 120. A cap 124 is mounted to the substrate 104. The cap 124 is made of an opaque material and includes a peripheral side wall and a front wall. Distal ends of the peripheral side wall are mounted to the substrate 104 using a suitable adhesive. Openings are provided in the front wall generally vertically aligned with the locations of the photosensitive region 116 for the sensor integrated circuit die 112 and the photoemission region 120 of the emitter integrated circuit die 114. An interior wall of the cap is positioned between the photosensitive region 116 and the mounting location for the emitter integrated circuit die 114. Each of the openings in the front wall of the cap 124 is covered with a transparent optical element 128 (such as, for example, including a lens and perhaps a filter) mounted by a suitable adhesive to an inside surface of the front wall of the cap 124 (or within the opening itself).

In operation, light is emitted from the photoemission region 120 of the emitter integrated circuit die 114 in response to control signaling generated by the sensor integrated circuit die 112. This light propagates through the transparent optical element 128a to outside of the package 100 to illuminate a target object. Light reflected by the target object returns to the package 100, passes through the transparent optical element 128b, and is detected by the photosensitive region 116. The sensor integrated circuit die 112 measures the difference in time between emission of the light by the emitter integrated circuit die 114 and sensing of the returned light reflected by the target object by the first photosensitive region 116, and then calculates the distance from package 100 to the target object as a function of the measured difference in time.

There is a need in the art for improved packaging of the sensor integrated circuit die 112 and the emitter integrated circuit die 114 mounted thereto. Such improved packaging should provide, for example, a smaller form factor especially in the z direction relative to package thickness. Such improved packaging should further support a lower manufacturing cost suited for high volume production. Still further, a stiffer and/or more robust package is desirable.

### SUMMARY

In an embodiment, a method comprises: at each of a plurality of integrated circuit areas for a silicon integrated circuit substrate wafer, forming at least one micro-dam structure surrounding a die area, wherein each micro-dam structure delimits a reservoir; dispensing a transparent material to fill each reservoir; molding an opaque material to laterally encapsulate the micro-dam structures filled by the transparent material; and singulating the silicon integrated circuit substrate wafer to form a plurality of packages.

The die area surrounded by the micro-dam structure may comprise one or more of a photosensitive region and an emitter integrated circuit mounted to the silicon integrated circuit substrate wafer.

Each micro-dam structure surrounding the die area is formed as a free-standing structure. The micro-dam structure is made by performing an additive manufacturing process to dispense a sequence of ring layers one on top of another to build the micro-dam structure surrounding the die area. Each ring layer is made of a dispensed line of material made, for example, of a curable adhesive.

Singulating the silicon integrated circuit substrate wafer may comprise cutting through one or the other of the transparent material or opaque material depending on the positioning of the micro-dam structure.

In an embodiment, a package comprises: a silicon integrated circuit substrate die including a die area; a micro-dam structure surrounding the die area, wherein the micro-dam structure delimits a reservoir; a transparent material filling the reservoir; and an opaque material laterally encapsulating the micro-dam structure filled by the transparent material.

The micro-dam structure comprises a sequence of ring layers stacked one on top of another to build the micro-dam structure surrounding the die area. Each ring layer is made of a dispensed line of material made, for example, of a curable adhesive.

A singulated edge of the package may pass through one or the other of the transparent material or the opaque material.

### BRIEF DESCRIPTION OF THE DRAWINGS

For a better understanding of the embodiments, reference will now be made by way of example only to the accompanying figures in which:

FIG. 1 is a cross-sectional view of a conventional time of flight (ToF) optical sensor package;

FIG. 2 is a cross-sectional view of an optical sensor package;

FIGS. 3A-3M show steps of a method for manufacturing the optical sensor package of FIG. 2; and

FIG. 4 is a cross-sectional view of an optical sensor package.

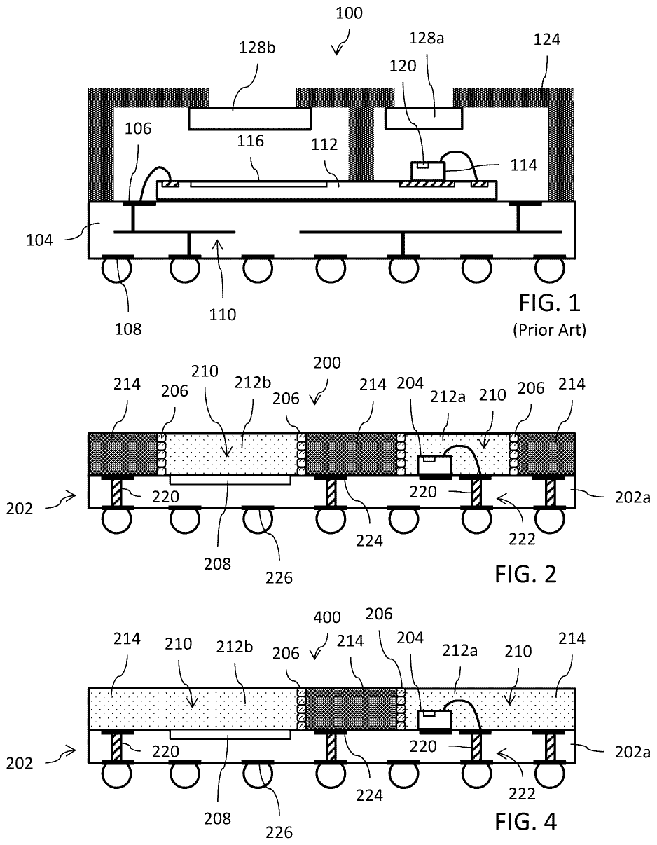

### DETAILED DESCRIPTION

In the following description, certain specific details are set forth in order to provide a thorough understanding of various aspects of the disclosed subject matter. However, the disclosed subject matter may be practiced without these specific details. In some instances, well-known structures and methods of semiconductor processing comprising embodiments of the subject matter disclosed herein have not been described in detail to avoid obscuring the descriptions of other aspects of the present disclosure.

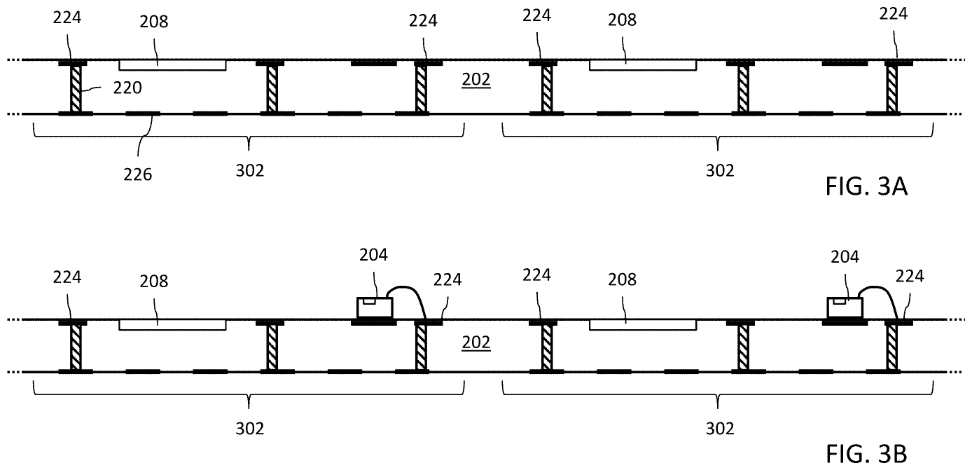

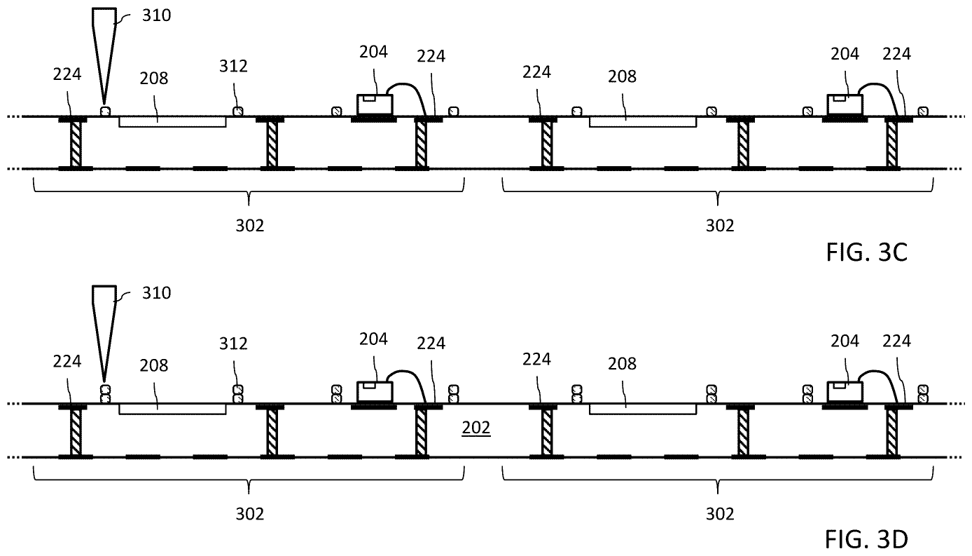

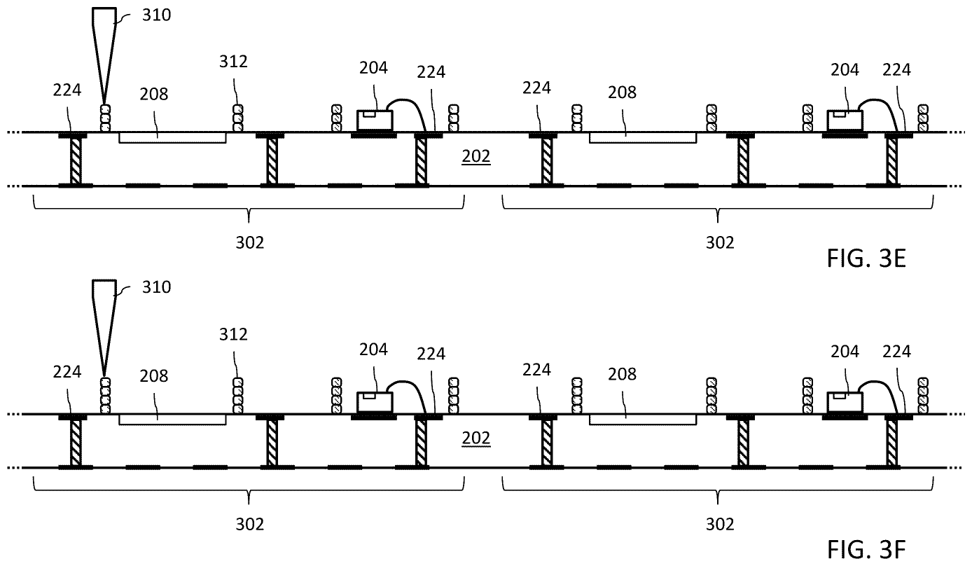

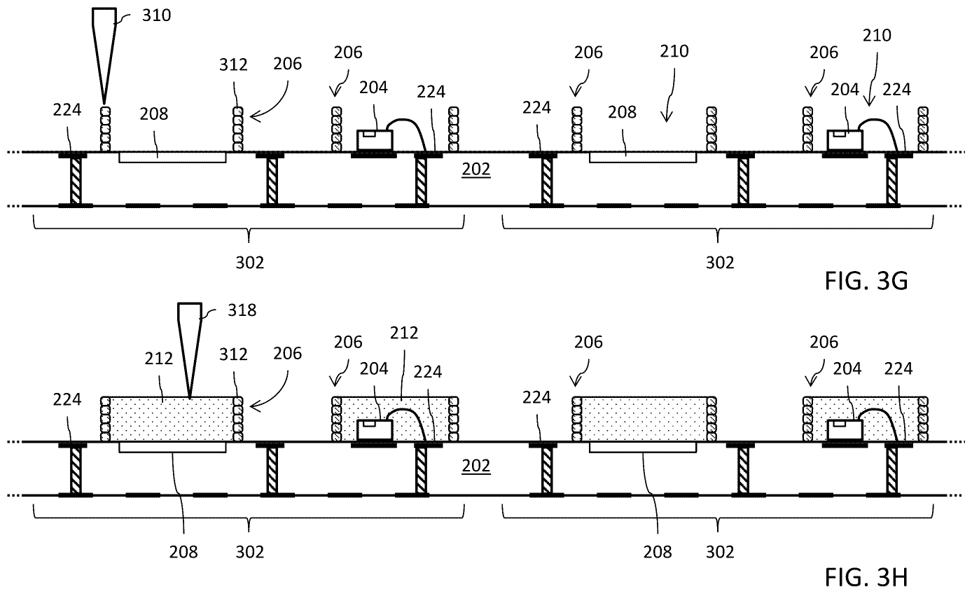

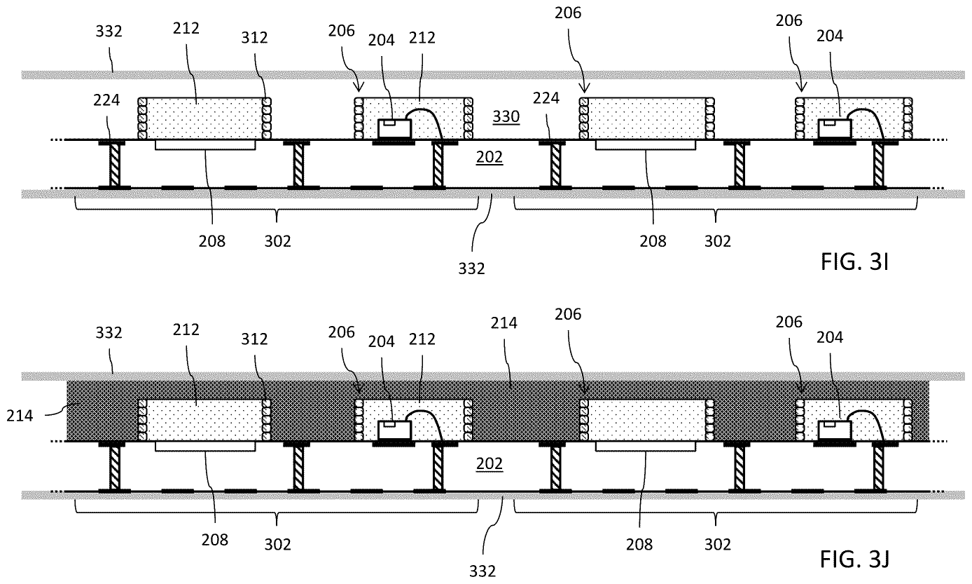

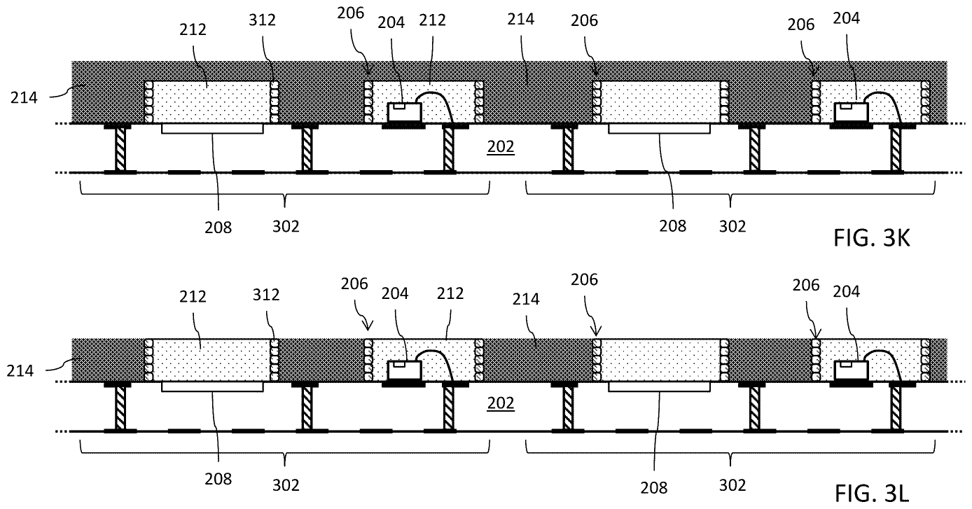

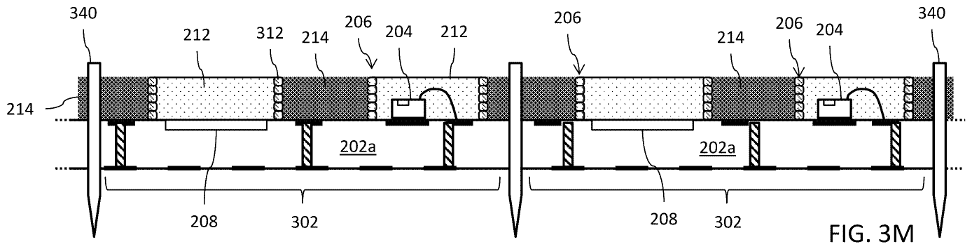

Reference is now made to FIG. 2 which shows a cross-sectional view of a wafer level optical sensor package 200. The wafer level optical sensor package 200 is fabricated as an integrated sensor package. Details of the wafer level manufacturing process are provided below and illustrated in FIGS. 3A-3M. Briefly, a substrate wafer 202 including a plurality of integrated circuit sensor dies 202a is fabricated. Emitter dies 204 are mounted to the substrate wafer at each integrated circuit die location. A plurality of micro-dam structures 206 are then formed (for example, formed by dispensed layers using additive manufacturing—such as three-dimensional (3D) printing or controlled dispensing—techniques) on the wafer 202 at locations which delimit die (or circuit) areas where the emitter dies 204 have been mounted and die (or circuit) areas where the photosensitive region 208 of the integrated circuit sensor dies 202 are located. The micro-dam structures 206 define a reservoir 210 at each of the locations. The reservoirs 210 are then filled with a transparent material 212. An opaque material 212 is then molded over the wafer 202 to laterally encapsulate the reservoirs delimited by the micro-dam structures 206 and filled with the transparent material 210. The molded wafer level structure is then singulated into individual optical sensor packages 200.

The optical sensor package 200 includes a sensor integrated circuit die 202a formed from the silicon integrated circuit substrate wafer 202. The sensor integrated circuit die 202a includes at least one photosensitive region 208. Through silicon vias form an electrical connection network 220 for electrically connecting front connection pads 224 of the sensor integrated circuit die 202a to a redistribution layer on the back side of the sensor integrated circuit die 202a which includes rear connection pads 226. An emitter integrated circuit die 204 is mounted to the front surface of the sensor integrated circuit die 202a and electrically connected to the front connection pads 224 (for example, by wirebonding). The die area of the sensor integrated circuit die 202a where the photosensitive region 208 is located is surrounded by a micro-dam structure 206. The die area of the sensor integrated circuit die 202a where the emitter integrated circuit die 204 is mounted is also surrounded by a micro-dam structure 206. These micro-dam structures 206 may, for example, be formed by a plurality of ring layers fabricated one on top of another using additive manufacturing—such as 3D printing or controlled dispensing—techniques to build the micro-dam structures, where the ring layers are stacked on top of each other until a desired height of the structures 206 is reached. Each instance of stacked ring layers provides the micro-dam structure 206 which defines an enclosed reservoir 210. The reservoirs 210 are filled by a transparent material 212. At the location of the emitter integrated circuit die 204, the transparent material 212 filling the reservoir covers and encapsulates the emitter integrated circuit die 204 forming a transparent optical element 212a. At the location of the photosensitive region 208, the transparent material 212 filling the reservoir covers and encapsulates the photosensitive region 208 forming a transparent optical element 212b. An opaque material 214 laterally encapsulates the reservoirs delimited by the micro-dam structures 206 and filled with the transparent material 210 to complete the package 200.

In operation, light is emitted from the photoemission region of the emitter integrated circuit die 204 in response to control signaling generated by the sensor integrated circuit die 202a. The emitted light propagates through the transparent optical element 212a to outside of the package 200 to illuminate a target object. Light reflected by the target object returns to the package 200, passes through the transparent optical element 212b, and is detected by the photosensitive region 208 of the sensor integrated circuit die 202a. The sensor integrated circuit die 202a measures the difference in time between emission of light by the emitter integrated circuit die 204 and the sensing of the returned light reflected by the target object by the photosensitive region 208. The distance from the package 200 to the target object is then determined as a function of the measured difference in time. It will be noted that the opaque material 212 blocks a more direct light path through the package between the emitter and photosensor which would introduce an error in the distance measurement.

Reference is now made to FIGS. 3A-3M which show steps of a method of manufacturing the package 200 of FIG. 2.

FIG. 3A—a silicon integrated circuit substrate wafer 202 is fabricated using conventional techniques well known to those skilled in the art. The thickness of the wafer 202 may, for example, be in a range of 50-100 μm. The wafer includes a plurality of integrated circuit areas 302 which are each fabricated at wafer level to include front connection pads 224 and a photosensitive region 208. Sufficient vacant space is provided between adjacent integrated circuit areas 302 to permit singulation at scribe lines to be performed in producing individual packages 200. Although the photosensitive regions 208 and the front connection pads 224 are illustrated as being located at the upper surface of the silicon integrated circuit substrate wafer 202, it will be understood that this is by way of a simplified illustration, it being understood by those skilled in the art that the photosensors for the photosensitive regions 208 are typically located at or within the semiconductor material of the wafer 202 and the front connection pads 224 are typically located in the metallization interconnect levels, which extend over the semiconductor material, of the wafer 202. The photosensitive regions 208 may, for example, be formed by an array of photosensors (such as photodiodes or single photon avalanche diodes (SPADs)). In a preferred implementation, the fabrication of the wafer is completed to include the through silicon via 220 structures as well as the back connection pads 226.

FIG. 3B—an emitter integrated circuit die 204 is mounted and wirebonded to the front connection pads 224 at each integrated circuit area 302.

FIGS. 3C to 3G—using additive manufacturing (such as 3D printing or controlled dispensing) techniques for controlled provision a building material through a tool 310, a stack of ring 312 layers are formed on the upper surface of the silicon integrated circuit substrate wafer 202 at each of the integrated circuit areas 302 to surround the die area where the photosensitive region 208 is located and to surround the die area where the emitter integrated circuit die 204 is mounted. The stack of ring 312 layers forms the micro-dam structure 206 enclosing each die area and which define at each die area a reservoir 210. In plan (i.e., top down) view, the ring layers and the resulting micro-dam structure 206 have any desired closed shape including circular, square, rectangular, etc., dependent on the size and shape of the die area which is to be delimited. Although FIG. 2 and FIGS. 3C to 3G show a micro-dam structure 206 including five stacked ring 312 layers formed in a sequential manner, it will be understood that this number of layers is by way of example only, and the total number of ring layers needed for each structure 206 is dependent on the desired height of the structure 206 and the thickness of each dispensed ring 312 layer. The stack of ring 312 layers is free-standing in that it need not be otherwise laterally supported or formed adjacent to and in contact with another structure to prevent toppling.

As a non-limiting example, the material used in the formation of each ring 312 layer may comprise the DELO DUALBOND EG4797 adhesive produced by DELO Industrie Klebstoffe GmbH & Co., where this curable adhesive material is well suited for use in the fabrication of freeform fine microstructures such as the individual ring layers of the micro-dam structures 206. The dispensed line of material forming the ring layers may, for example, have a line width that is less than about 100 μm. The micro-dam structures 206 may, for example, have a height of about 500 μm. The tool 310 for dispensing the curable adhesive material may, for example, comprise a micro-dispenser produced by NSW Automation.

Following completion of the dispensing of the material for forming the ring 312 layers, a suitable curing operation may be performed to harden the dispensed material.

FIG. 3H—each reservoir 210 delimited by the micro-dam structures 206 formed by stacked ring 312 layers is then filled with a transparent material 212 dispensed into the reservoir 210 by a dispensing tool 318. At the location of the emitter integrated circuit die 204, the transparent material 212 filling the reservoir covers and encapsulates the emitter integrated circuit die 204 (to form the transparent optical element 212a). At the location of the photosensitive region 208, the transparent material 212 filling the reservoir covers and encapsulates the photosensitive region 208 (to form the transparent optical element 212b).

Following completion of the dispensing of the transparent material 212, a suitable curing operation may be performed to harden the dispensed material.

It will be noted that the dispensing of the transparent material 212 may result in the presence of material extending vertically above the top edges of the micro-dam structures 206. This over-filling of the reservoirs 210, if present, is addressed at a later step in the manufacturing process. The illustration in FIG. 3H of the top of the filling transparent material 212 coincident with the top of edges of the micro-dam structures 206 is exemplary and idealized.

FIG. 3I—the wafer scale structure illustrated in FIG. 3H is the placed within the cavity 330 of a two-part mold 332.

FIG. 3J—an opaque material 214 is then injected in the cavity 330 of the mold 332 and allowed to cure. The opaque material 214 laterally encapsulates the reservoirs delimited by the micro-dam structures 206 and filled with the transparent material 212.

FIG. 3K—the opaque material encapsulated wafer scale structure is then removed from the mold 332.

FIG. 3L—a grinding operation is then performed to recess the opaque material 214 to a level coincident with the top edges of the micro-dam structures 206. This grinding operation will also remove transparent material 212 (if present) which has over-filled the reservoirs 210.

Additionally, solder balls are attached to the rear connection pads 226 (not explicitly shown, see FIG. 2). The solder balls may be arranged, for example, in ball grid array pattern.

FIG. 3M—a singulation process using a cutting tool 340 dices the wafer 202 into a plurality of packages 200 (see, FIG. 2) each including a die 202a. The cutting tool 340 passes through the opaque material encapsulated wafer scale structure in a scribe area located between integrated circuit areas 302. It will be noted that attachment of solder balls may instead be performed after singulation.

FIG. 4 is a cross-sectional view of an optical sensor package 400. Like references in FIGS. 2 and 4 refer to same or similar components. The package 400 differs from the package 200 in that the micro-dam structures 206 surround a die area that includes both the die area where the photosensitive region 208 is located (on one integrated circuit area 302) and the die area where the emitter integrated circuit die 204 is mounted (on another adjacent integrated circuit area 302). The package 400 also differs from the package 200 in that the singulation performed at the scribe line between areas 302 cuts through the dispensed and cured transparent material 212 instead of the opaque material 214. Thus, in package 200 the singulated edge of the package passes through the opaque material, while in the package 400 the singulated edge of the package passes through the transparent material. The process of FIGS. 3A to 3M may be used as well to fabricate the packages 400 subject to a change at FIGS. 3C to 3G with respect to the location, size and shape of the ring layers which provide the micro-dam structures defining the reservoirs within which the transparent material is dispensed.

In a preferred implementation, the package 200, 400 is a component of an electronic device such as a smart phone. More specifically, the package 200, 400 may, for example, be integrated into or with a touch screen of the electronic device.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

What is claimed is:

1. A method, comprising:
at each of a plurality of integrated circuit areas for a silicon integrated circuit substrate wafer, forming at least one micro-dam structure surrounding a die area, wherein each micro-dam structure delimits a reservoir;
dispensing a transparent material to fill each reservoir;
molding an opaque material to laterally encapsulate the micro-dam structures filled by the transparent material; and
singulating the silicon integrated circuit substrate wafer to form a plurality of packages.

2. The method of claim 1, wherein the die area comprises a photosensitive region, and wherein the micro-dam structure surrounds the photosensitive region.

3. The method of claim 2, wherein the transparent material filling the reservoir delimited by the micro-dam structure surrounding the photosensitive region forms a transparent optical element covering the photosensitive region.

4. The method of claim 3, wherein singulating the silicon integrated circuit substrate wafer comprises cutting through the opaque material between integrated circuit areas of the silicon integrated circuit substrate wafer.

5. The method of claim 1, wherein the die area comprises an emitter integrated circuit mounted to the silicon integrated circuit substrate wafer, and wherein the micro-dam structure surrounds the emitter integrated circuit.

6. The method of claim 5, wherein the transparent material filling the reservoir delimited by the micro-dam structure surrounding the emitter integrated circuit forms a transparent optical element encapsulating the emitter integrated circuit.

7. The method of claim 6, wherein singulating the silicon integrated circuit substrate wafer comprises cutting through the opaque material between integrated circuit areas of the silicon integrated circuit substrate wafer.

8. The method of claim 1, wherein the die area comprises a photosensitive region, wherein an emitter integrated circuit mounted to the silicon integrated circuit substrate wafer, and wherein the micro-dam structure surrounds the photosensitive region and the emitter integrated circuit.

9. The method of claim 8, wherein the transparent material filling the reservoir delimited by the micro-dam structure surrounding the photosensitive region and the emitter integrated circuit forms a transparent optical element covering the photosensitive region and the emitter integrated circuit.

10. The method of claim 9, wherein singulating the silicon integrated circuit substrate wafer comprises cutting through the transparent material between integrated circuit areas of the silicon integrated circuit substrate wafer.

11. The method of claim 1, wherein each micro-dam structure surrounding the die area is a free-standing structure.

12. The method of claim 1, wherein forming each one micro-dam structure comprises performing an additive manufacturing to dispense a sequence of ring layers one on top of another to build the micro-dam structure surrounding the die area.

13. The method of claim 12, wherein each ring layer is formed by a line of material.

14. The method of claim 13, wherein the material is made of a curable adhesive.

15. A package made by the method of claim 1.

16. A package, comprising:
a silicon integrated circuit substrate die including a die area;
a micro-dam structure surrounding the die area, wherein the micro-dam structure delimits a reservoir;
a transparent material filling the reservoir; and
an opaque material laterally encapsulating the micro-dam structure filled by the transparent material.

17. The package of claim 16, wherein the micro-dam structure comprises a sequence of ring layers stacked one on top of another to build the micro-dam structure surrounding the die area.

18. The package of claim 17, wherein each ring layer is formed by a line of material.

19. The package of claim 18, wherein the material is a cured adhesive.

20. The package of claim 16, wherein a singulated edge of the package passes through the opaque material.

21. The package of claim 16, wherein a singulated edge of the package passes through the transparent material.

22. The package of claim 16, wherein the die area comprises a photosensitive region, and wherein the micro-dam structure surrounds the photosensitive region.

23. The package of claim 16, wherein the die area comprises an emitter integrated circuit mounted to the silicon integrated circuit substrate wafer, and wherein the micro-dam structure surrounds the emitter integrated circuit.
